(19) United States
(12) Patent Application Publication
(10) Pub. No.: US 2015/0382485 A1
(43) Pub. Date: Dec. 31, 2015

(54) ELECTRONIC DISPLAY DEVICE AND METHOD FOR ASSEMBLING THE SAME

(71) Applicant: InnoLux Corporation, Miao-Li County (TW)

(72) Inventors: Yi-Yu CHEN, Miao-Li County (TW); Ching-I LO, Miao-Li County (TW)

(21) Appl. No.: 14/732,000

(22) Filed: Jun. 5, 2015

(30) Foreign Application Priority Data
Jun. 27, 2014 (TW) 103122214

(51) Int. Cl. H05K 5/00; H05K 7/18

(52) U.S. Cl. CPC H05K 5/0017; H05K 7/18

(57) ABSTRACT

Embodiments of assembling an electronic display device are provided. The method includes providing a first member and a second member. The first member has a recess, and a through hole is formed at the recess. The second member is positioned over a side of the first member that is opposite to the side where the recess is formed. The method further includes having an assembly member in the through hole. The method also includes providing a mold to compress the connecting member to form a connecting structure to connect the first member and the second member. Afterwards, the mold is removed.

### CROSS REFERENCE TO RELATED APPLICATIONS

This Application claims priority of Taiwan Patent Application No. 103122214, filed on Jun. 27, 2014, the entirety of which is incorporated by reference herein.

### BACKGROUND OF THE INVENTION

1. Field of the Invention

The present invention relates to an electronic display device and a method for assembling the electronic display device, and more particularly to an electronic display device that includes deformable material to connect different members and a method for assembling the electronic display device.

2. Description of the Related Art

An electronic display device is an optoelectronic device able to transfer electric signals into visible images so that human beings can see the information contained in the electronic signals. LCDs (Liquid-Crystal displays), PDP (plasma display panel) displays, EL (electro luminescence) displays, FEDs (field emission displays), and DMD (deformable mirror device) displays have gained great popularity.

Because of their slimness, low power consumption and low radiation, these image-display devices have been widely used in portable electronic devices such as desktop computers, notebook computers, personal digital assistants (PDAs), and mobile phones, and are even gradually replacing cathode ray tube (CRT) monitors and conventional TVs.

To satisfy the requirements of slimness and light weight expected of portable electronic products, manufacturers have to concern the flatness of the external appearance of the products, so as to install various elements within the limited internal space of the products. Although existing methods and devices for assembling the image display device have been generally adequate for their intended purposes, they have not been entirely satisfactory in all respects.

### BRIEF SUMMARY OF THE INVENTION

Consequently, objective of the disclosure is to provide an electronic display device which is easy to assemble and has a flat external appearance.

According to one embodiment of the disclosure, the electronic display device includes a housing. The housing includes a first member, a second member, and a connecting structure. The first member has a recess, and a through hole is formed at the recess. The second member is configured to support the first member. The connecting structure connects the first member and the second member. The connecting structure is positioned in the though hole and covers the bottom surface of the recess.

In the above-mentioned embodiment, the connecting structure includes a connecting portion and a fixing portion. The connecting portion is positioned in the through hole and connects to the second member. The fixing portion is positioned in the recess and covers the bottom surface of the recess. The width of the fixing portion is greater than the width of the through hole. The connecting portion includes a hook structure.

In the above-mentioned embodiment, the fixing portion includes thermoplastic material, thermosetting material, or light cured material.

In the above-mentioned embodiment, the first member has a front surface adjacent to the bottom surface of the recess, and an included angle is formed between the bottom surface and the front surface. The included angle ranges from about 90 degrees to about 160 degrees.

In the above-mentioned embodiment, the first member has a front surface, and a height difference between the bottom surface and the front surface ranges from about 0.1 mm to about 0.7 mm.

In the above-mentioned embodiment, the connecting structure and the second member are formed integrally.

In the above-mentioned embodiment, the electronic display device further includes a display panel, wherein the display panel is positioned in the housing.

In the above-mentioned embodiment, the top surface of the connecting structure and the front surface of the first member are located in the same plane.

The other objective of the disclosure is to provide a method for assembling an electronic display device. According to one embodiment of the disclosure, the method for assembling an electronic display device includes: providing a first member, wherein the first member has a recess, and a through hole is formed at the recess; placing a second member over a side of the first member that is opposite to the side where the recess is formed; having an assembly member in the through hole; providing a mold; compressing the assembly member by the mold to form a connecting structure to connect the first member and the second member; and removing the mold.

In the above-mentioned embodiment, in the step of providing a mold, the method further includes heating the mold to a specific temperature.

### BRIEF DESCRIPTION OF THE DRAWINGS

The present invention is more fully understood by reading the subsequent detailed description and examples with references made to the accompanying drawings, wherein:

FIG. 1 shows a flow chart of a method for assembling an electronic display device, in accordance with one embodiment of the disclosure;

FIG. 2A shows a schematic view of some elements of an electronic display device, in accordance with one embodiment of the disclosure;

FIGS. 2B-2E show schematic views of a method for assembling an electronic display device, in accordance with one embodiment of the disclosure;

FIG. 3 shows an exploded view of an electronic display device, in accordance with one embodiment of the disclosure;

FIG. 4 shows a cross-sectional view of an electronic display device, in accordance with one embodiment of the disclosure;

FIG. 5 shows a cross-sectional view of an electronic display device, in accordance with one embodiment of the disclosure; and

FIG. 6 shows a cross-sectional view of an electronic display device, in accordance with one embodiment of the disclosure.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

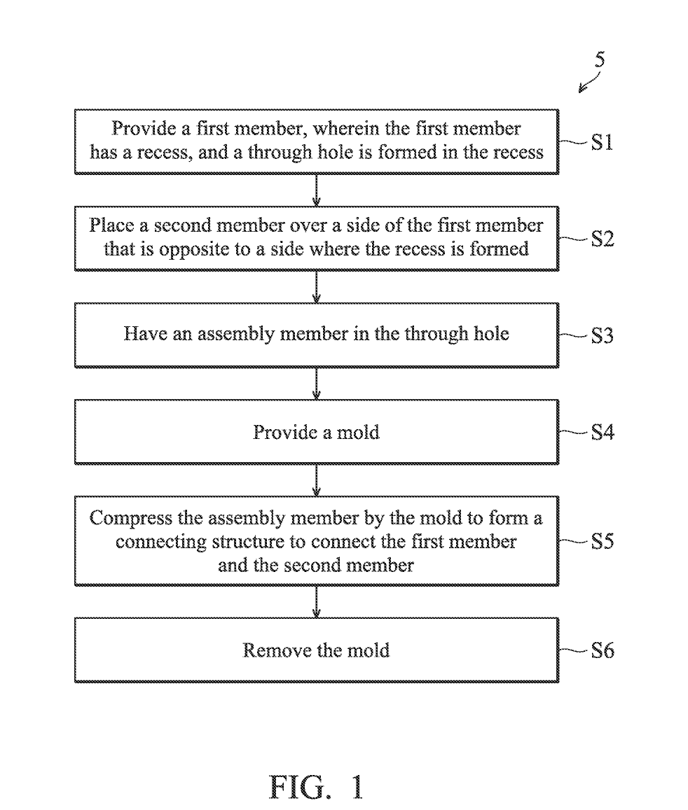

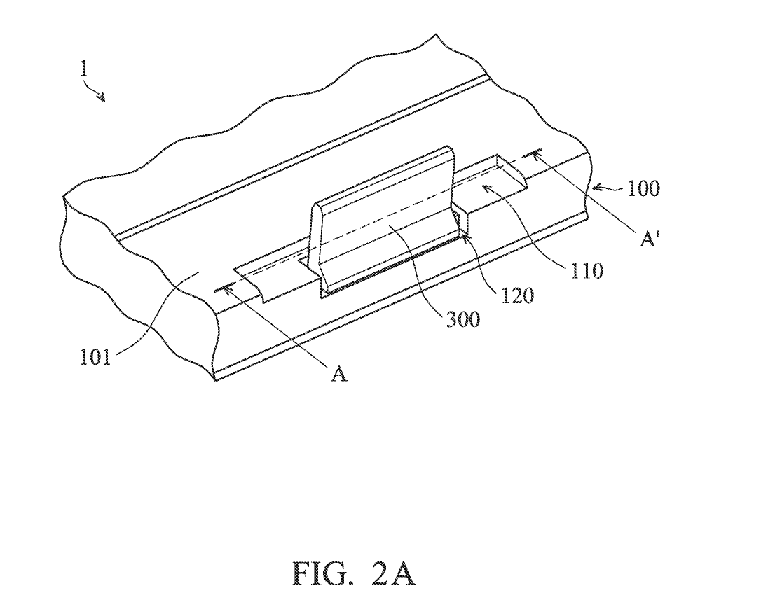

Referring to FIG. 1 with reference to FIGS. 2A to 2E, FIG. 1 shows a flow chart of a method 5 for assembling an electronic display device, FIG. 2A shows a schematic view of some elements of an electronic display device 1, and FIGS. 2B-2E show schematic views of using the method 5 for assembling the electronic display device 1, wherein FIGS. 2B-2E are cross-sectional views observed from the A-A′ line of FIG. 2A.

The method 5 for assembling an electronic display device (such as the electronic display device 1 shown in FIG. 2A) begins from step S1. In step S1, a first member (such as a first member 100 shown in FIG. 2A) is provided. In one embodiment, as shown in FIGS. 2A and 2B, the first member 100 has a front surface 101 and a rear surface 103. The front surface 101 is opposite to the rear surface 103. The first member 100 has a recess 110, and the recess 110 has a bottom surface 111. The height difference between the front surface 101 of the first member 100 and the bottom surface 111 of the recess 110 is H. In one embodiment, the height difference H ranges from about 0.1 mm to about 0.7 mm.

In one embodiment, the bottom surface 111 of the recess 110 is perpendicular to a side wall 113 of the recess 111, and the side wall 113 of the recess 111 is perpendicular to the front surface 101 of the first member 100. In one embodiment, the bottom surface 111 of the recess 110 is planar. An extension direction of the bottom surface 111 of the recess 110 is parallel to the extension direction of the front surface 101 of the first member 100, however the disclosure should not be limited thereto. In the other embodiment, the bottom surface of the recess is a curved surface and is immediately adjacent to the front surface of the first member. In addition, the bottom surface 111 of the recess 110 may be rectangular, circular, or any other form.

A through hole 120 penetrates the recess 110 and the rear surface 103 of the first member 100. In one embodiment, the through hole 120 is positioned at a substantial center of the recess 110. In one embodiment, the through hole 120 has a width that is not uniform. For example, in a direction from the front surface 101 to the rear surface 103 of the first member 100, the width of the through hole 120 progressively decreases or increases. In one embodiment, the inner surface of through hole 120 has one or more positioning members extending toward the center of the through hole 120, so as to facilitate the positioning of the element (such as an assembly member 300) that passes through the through hole 120.

The method 5 for assembling the electronic display device continues in step S2. In step S2, a second member (such as the second member 200) is placed at a side of the first member 100 that is opposite to the side of the first member 100 where the recess 110 is formed. In one embodiment, as shown in FIG. 2B, the first member 100 is directly supported by the second member 200, however the disclosure should not be limited thereto. In the other embodiment, the second member 200 is separated by the rear surface 103 of the first member 100 by a distance. The second member 200 is not in contact with the first member 100. Additionally, some elements of the electronic display device, such as a reflective sheet, light guide plate, optical sheet, and light source assembly, etc., are positioned between the first member 100 and the second member 200. In one embodiment, at least a portion of the surface of the second member 200 corresponds to the though hole 120. That is, a portion of the surface of the second member 200 communicates with the through hole 120 so that an element (such as the assembly member 300) that connects the first member 100 and the second member 200 is able to pass therethrough.

The method 5 for assembling the electronic display device continues to step S3. In step S3, an assembly member (such as the assembly member 300) is disposed in the through hole 120. In one embodiment, as shown in FIG. 2B, the assembly member 300 and the second member 200 are formed integrally. The step S3 is finished as the step S2 is performed, however the disclosure should not be limited thereto.

In one embodiment, the width of the assembly member 300 is less than or equal to the width of the through hole 120. In the other embodiment, the assembly member 300 has a width that is not uniform. For example, in a direction away from the second member 200, the width of the assembly member 300 progressively decreases for the ease of the insertion of the assembly member 300. In one embodiment, the assembly member 300 includes thermoplastic material which becomes pliable or moldable above a specific temperature and returns to a solid state upon cooling, however the disclosure should not be limited thereto. In the other embodiment, the assembly member 300 includes thermosetting material, or light cured material.

The method 5 for assembling the electronic display device continues to step S4. In step S4, a mold (such as mold 400) is provided. In one embodiment, as shown in FIG. 2B, the mold 400 has a mold cavity 410. The mold cavity 410 corresponds to the through hole 120, and the width of the mold cavity 419 is greater than the width of the through hole 120 but less than the width of the recess 110.

The method 5 for assembling the electronic display device continues to step S5. In step S5, the assembly member 300 is compressed by the mold 400 to form a connecting structure 310 to connect the first member 100 and the second member 200. In one embodiment, before the step S5 is performed, the method 5 for assembling the electronic display device further includes heating the mold 400 400 to a specific temperature. In one embodiment, the through hole 120 is filled by the assembly member 300 while the step S5 is performed.

In the other embodiment, the mold cavity of the mold 400 is eliminated. The profile of the surface of the mold that faces the first member 100 corresponds to the profile of the front surface 101 of the first member 100. For example, the surface of the mold that faces the first member 100 and the front surface 101 of the first member 100 are planar surfaces. Therefore, to compress the assembly member 300, the surface of the mold 400 abuts the front surface 101 of the first member 100, and the assembly member 300 may be freely deformed in the recess 120 after being compressed by the surface of the mold.

The method 5 for assembling the electronic display device continues to step S6. In step S6, the mold 400 is removed. In one embodiment, after the mold 400 is removed, the connecting structure 310 is cooled and solidified. As a result, the first member 100 is stably connected to the second member 200 by the connecting structure 310, and the process of assembling the first member 100 and the second member 200 of the electronic display device 1 is finished.

In one embodiment, as shown in FIG. 2D, after solidification, the connecting structure 310 includes a connecting portion 311 and a fixing portion 313. The connecting portion 311 is positioned in the through hole 120 and connected to the second member 200. The fixing portion 313 is connected to the connecting portion 311 and positioned in the recess 110. The width of the fixing portion 313 is greater than the width of the through hole 120, and the bottom surface 111 of the recess 110 is covered by the fixing portion 313.

In one embodiment, in order to enhance the mechanical structure, the fixing portion 313 of the connecting structure 310 has a thickness of T. The thickness T ranges from about 0.1 mm to about 0.7 mm. In one embodiment, the thickness of T of the fixing portion 313 of the connecting structure 310 is less than or equal to the depth (the height difference H between the front surface 101 and the bottom surface 111) of the recess 110. That is, the top surface 3131 of the fixing portion 313 and the front surface 101 of the first member 100 are substantially located at the same reference plane R, however the disclosure should not be limited thereto. The connecting structure 310 may protrude to the outside of the recess 110.

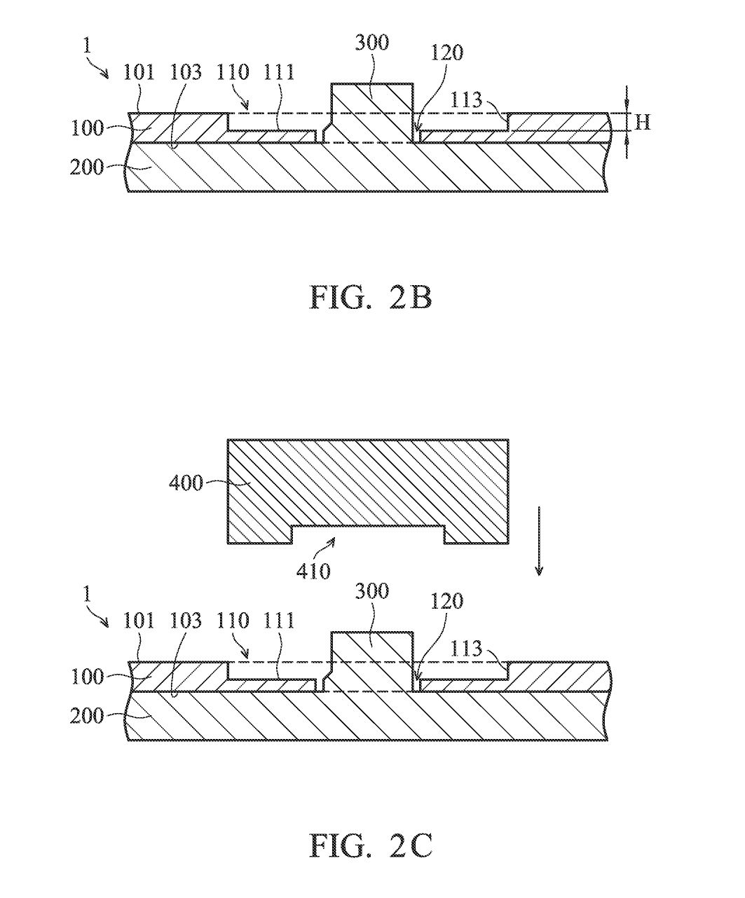

The method 5 for assembling the electronic display device may be applied to assemble any two members of the electronic display device 1. For example, as shown in FIG. 3, the electronic display device 1 includes a housing 2 and a display panel 500. The housing 2 includes the first member 100, the second member 200, and the assembly member 300. The first member 100 and the second member 200 of the electronic display device 1 are assembled through the method 5, and the display panel 500 is positioned over the housing 2, however the disclosure should not be limited thereto. In the other embodiment, the first member 100 and the second member 200 of the electronic display device 1 are assembled through the method 5, and the display panel 500 is positioned within the housing 2. In the other embodiment, the method 5 is applied to assemble a rear bezel (refer to the first member) and a plastic frame (refer to the second member) of the electronic display device 1. Alternatively, the method 5 is applied to assemble a rear bezel (refer to the first member) and a light guide plate (refer to the second member) of the electronic display device 1. Alternatively, the method 5 is applied to assemble a member (refer to the first member) that includes thermoplastic material and another member (refer to the second member) that includes non-thermoplastic material of the electronic display device 1.

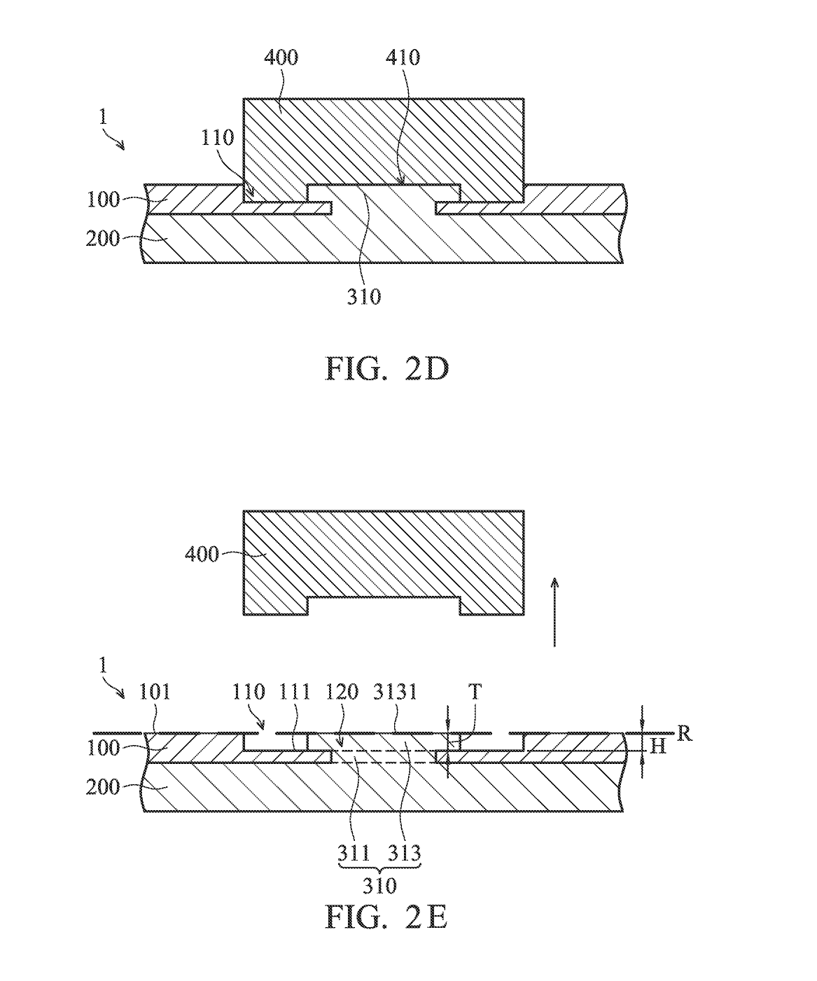

Referring to FIG. 4, FIG. 4 shows a cross-sectional view of an electronic display device 1a, in accordance with one embodiment of the disclosure. In the embodiment, elements that are similar to the elements shown in FIGS. 2A-2E are designated with the same or similar reference numbers, and the features of the elements are omitted for the sake of brevity. Difference between the electronic display device 1a and the electronic display device 1 includes the connecting member 310 of the electronic display device 1 being replaced by the connecting member 310a.

The connecting member 310a includes a connecting portion 311a and a fixing portion 313a. In one embodiment, the connecting portion 311a includes a hook structure. The connecting portion 311a and the second member 200 are formed integrally, and the connecting portion 311a doesn't include thermoplastic material or thermosetting material. When the second member 200 is connected to the first member 100, the connecting portion 311a penetrates the through hole 120. In addition, after the second member 200 is connected to the first member 100, the connecting portion 311a protrudes to the outside of the through hole 120 and engages with the bottom surface 111 of the recess 110. The fixing portion 313a may include thermoplastic material, thermosetting material. For example, the fixing portion 313a may be selected from the group including Polycarbonate (PC), Polyvinyl chloride (PVC), AB adhesive, Epoxy resins, Acrylic Adhesive, etc. The fixing member 313a is formed by dispensing or hot pressing so as to fix the connecting portion 311a. As a result, the first member 100 is stably connected to the second member 200.

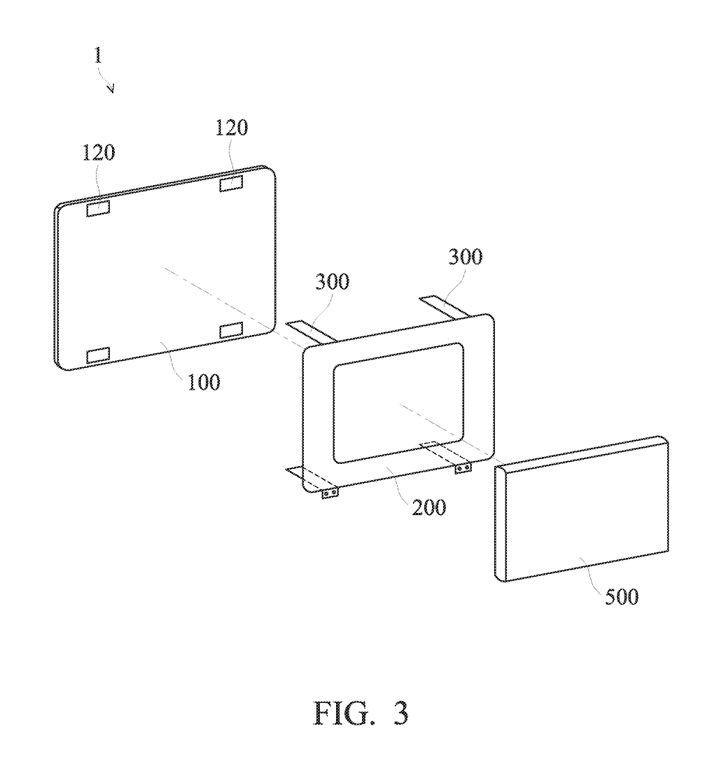

Referring to FIG. 5, FIG. 5 shows a cross-sectional view of an electronic display device 1b, in accordance with one embodiment of the disclosure. In the embodiment, elements that are similar to the elements shown in FIGS. 2A-2E are designated with the same or similar reference numbers, and the features of the elements are omitted for the sake of brevity. Difference between the electronic display device 1b and the electronic display device 1 includes the first member 100 of the electronic display device 1 being replaced by the first member 100b and the connecting member 310 of the electronic display device 1 being replaced by the connecting member 310b.

In one embodiment, the first member 100b has a recess 110b, and the first member has a front surface 101b. The bottom surface 111b of the recess 110b is an oblique plane and is positioned immediately adjacent to the front surface 101b of the first member 100b. In one embodiment, an included angle θ is formed between the front surface 101b of the first member 100b and the bottom surface 111b of the recess 110b, the included angle θ ranges from about 90 degrees to about 160 degrees.

A through hole 120 penetrates the bottom surface 111b of the recess 110b and the rear surface 103b of the first member 100b. In one embodiment, the through hole 120 is positioned at a substantial center of the recess 110a. The connecting portion 311b of the connecting member 310b is positioned in the through hole 120 and connected to the second member 200. The fixing portion 313b of the connecting member 310b is connected to the connecting portion 311b and positioned in the recess 110b. The width of the fixing portion 313b is greater than the width of the through hole 120, and a portion of the bottom surface 111b of the recess 110b is covered by the fixing portion 313b. In some embodiments, the electronic display device 1b is assembled through the method 5 as shown in FIG. 1.

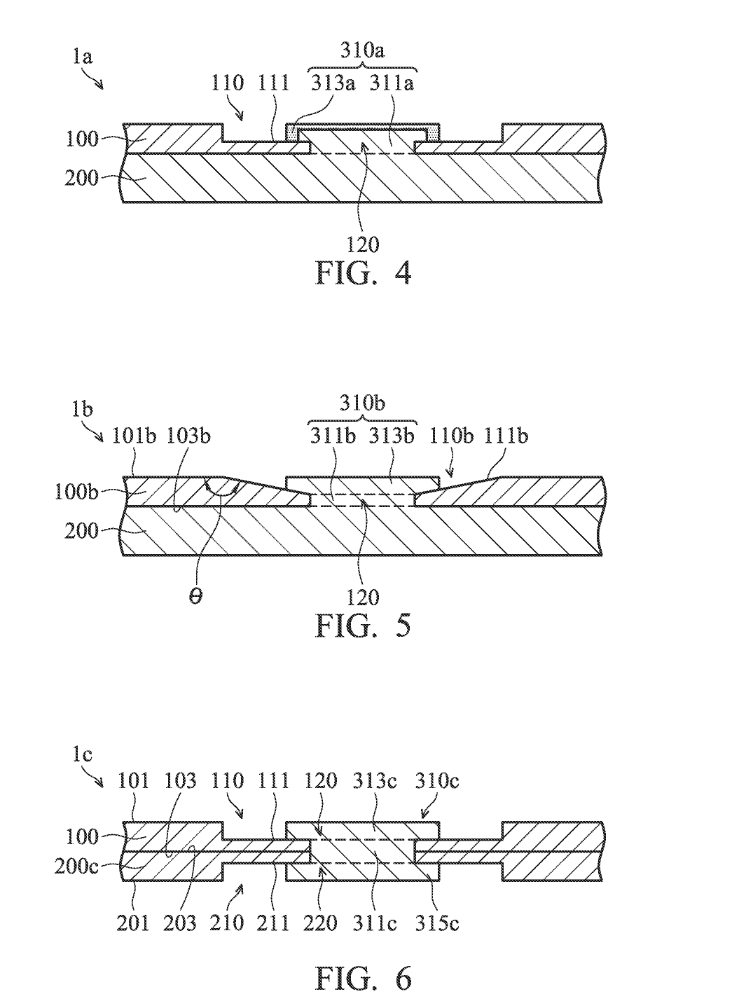

Referring to FIG. 6, FIG. 6 shows a cross-sectional view of an electronic display device 1c, in accordance with one embodiment of the disclosure. In the embodiment, elements that are similar to the elements shown in FIGS. 2A-2E are designated with the same or similar reference numbers, and the features of the elements are omitted for the sake of brevity. Difference between the electronic display device 1c and the electronic display device 1 includes the second member 200 of the electronic display device 1 being replaced by a second member 200c and the connecting member 310 of the electronic display device 1 being replaced by the connecting member 310c.

The second member 200c has a front surface 201 and a rear surface 203. The front surface 201 is opposite to the rear surface 203, and the rear surface 203 connects to the rear surface 103 of the first member 100. Additionally, the second member 200c has a recess 210.

In one embodiment, the bottom surface 211 of the recess 210 is planar. An extension direction of the bottom surface 211 of the recess 210 is parallel to an extension direction of the front surface 201 of the second member 200c, however the disclosure should not be limited thereto. In the other embodiment, the bottom surface of the recess is a curved surface, and the bottom surface of the recess is immediately adjacent to the front surface. In addition, the shape of the bottom surface 211 of the recess 210 may be rectangular, circular, or any other form.

A through hole 220 penetrates the recess 210. In one embodiment, the through hole 220 has a width that is not uniform. For example, in a direction from the front surface 201 to the rear surface 203 of the second member 200c, the width of the through hole 220 progressively decreases or increases. In one embodiment, the inner surface of through hole 220 has one or more positioning members extending toward the center of the through hole 220, so as to facilitate the positioning of the element that passes through the through hole.

The connecting structure 310c includes a connecting portion 311c and two fixing portions 313c and 315c. The connecting portion 311c is positioned in the through hole 220 and connected to the two fixing portions 313c and 315c. The fixing portion 313c is positioned in the recess 110, and the fixing portion 315c is positioned in the recess 210. The width of each two fixing portions 313c and 315c is greater than the width of each two through holes 120 and 220. Therefore, the bottom surface 111 of the recess 110 is covered by the fixing portion 313c, and the bottom surface 211 of the recess 210 is covered by the fixing portion 315c.

In one embodiment, the electronic display device 1c is assembled through the method 5 as shown in FIG. 1. For example, an assembly member including thermoplastic material is first placed in the through holes 120 and 220, and the assembly member is compressed by two molds to form the two fixing portions 313c and 315c. After the connecting structure 310c is cooled down and solidified, the process to assemble the first member 100 and the second member 200c is finished.

With the method for assembling the electronic display device of the disclosure, the first member and the second member are stably assembled in an assembly process. As a result, the stability of the electronic display device is improved. In addition, since at least a portion of the connecting structure or the whole portion of the connecting structure is positioned in the recess of the first member, the electronic display device has a flat external appearance. Therefore, the overall size of the electronic display device is optimized.

While the invention has been described by way of example and in terms of preferred embodiment, it is to be understood that the invention is not limited thereto. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An electronic display device, comprising:
a housing, comprising:
a first member, wherein the first member has a recess, and a through hole is formed at the recess;
a second member, wherein the second member is configured to support the first member; and
a connecting structure, connecting the first member and the second member, wherein the connecting member is positioned in the though hole and covers the bottom surface of the recess.

2. The electronic display device as claimed in claim 1, wherein the connecting structure comprises:
a connecting portion, positioned in the through hole and connected to the second member; and
a fixing portion, positioned in the recess and covering the bottom surface of the recess, wherein the width of the fixing portion is greater than the width of the through hole.

3. The electronic display device as claimed in claim 2, wherein the connecting portion comprises a hook structure.

4. The electronic display device as claimed in claim 3, wherein the fixing portion comprises thermoplastic material, thermosetting material, or light cured material.

5. The electronic display device as claimed in claim 1, wherein the first member has a front surface adjacent to the bottom surface of the recess, and an included angle is formed between the bottom surface and the front surface, the included angle ranges from about 90 degrees to about 160 degrees.

6. The electronic display device as claimed in claim 1, wherein the first member has a front surface, and a height difference between the bottom surface of the recess and the front surface of the first member ranges from about 0.1 mm to about 0.7 mm.

7. The electronic display device as claimed in claim 2, wherein the connecting structure and the second member are formed integrally.

8. The electronic display device as claimed in claim 1, further comprising a display panel, wherein the display panel is positioned in the housing.

9. A method for assembling an electronic display device, comprising steps of:
providing a first member, wherein the first member has a recess, and a through hole is formed in the recess;
placing a second member over a side of the first member that is opposite to the side where the recess is formed;
having an assembly member in the through hole;
providing a mold;
compressing the assembly member by the mold to form a connecting structure to connect the first member and the second member; and
removing the mold.

10. The method as claimed in claim 9, wherein the step of providing a mold further comprises heating the mold to a specific temperature.
